(19) United States
(12) Patent Application Publication
(10) Pub. No.: US 2025/0357135 A1
(43) Pub. Date: Nov. 20, 2025

(54) HIGH ASPECT RATIO ETCH WITH A METAL OR METALLOID CONTAINING MASK

(71) Applicant: Lam Research Corporation, Fremont, CA (US)

(72) Inventors: Gregory Clinton VEBER, Oakland, CA (US); Ming-Yuan CHUANG, San Jose, CA (US); Ragesh PUTHENKOVILAKAM, Portland, OR (US); Kapu Sirish REDDY, Portland, OR (US); Sonal BHADAURIYA, Beaverton, OR (US); Yongsik YU, Northridge, CA (US); Amit MUKHOPADHYAY, Fremont, CA (US); Qing XU, Fremont, CA (US); Merrett WONG, Palo Alto, CA (US)

(21) Appl. No.: 18/872,548

(22) PCT Filed: Jun. 16, 2023
(86) PCT No.: PCT/US2023/025567

§ 371 Date: Dec. 6, 2024

Related U.S. Application Data
(60) Provisional application No. 63/355,040, filed on Jun. 23, 2022.

(51) Int. Cl. H01L 21/311

(52) U.S. Cl. CPC H01L 21/31116; H01L 21/31144

(57) ABSTRACT

A method for etching features in a stack is provided. A metal or metalloid containing mask is formed over the stack. The stack is etched through the metal or metalloid containing mask, wherein the etching sputters metal or metalloid in the metal or metalloid containing mask and the sputtered metal or metalloid physically redeposits on sidewalls of features etched in the stack as a sputtered metal or metalloid containing passivation layer.

### CROSS-REFERENCE TO RELATED APPLICATION

This application claims the benefit of priority of U.S. Application No. 63/355,040, filed Jun. 23, 2022, which is incorporated herein by reference for all purposes.

### BACKGROUND

The disclosure relates to a method of forming semiconductor devices on a semiconductor wafer.

In forming semiconductor devices, etch layers may be etched to form memory holes or lines or other semiconductor features. Some semiconductor devices may be formed by etching a single stack of silicon dioxide also known as silicon oxide (SiO₂), for example, to form a capacitor in dynamic access random memory (DRAM). Other semiconductor devices may be formed by etching stacks of bilayers of alternating silicon dioxide (oxide) and silicon nitride (nitride) (ONON), or alternating silicon dioxide and polysilicon (OPOP). Other stacks of alternating layers may be etched. Some of the stacks of alternating layers may have one of the layers of the alternating layers that is silicon oxide. Some alternating layers may be alternating trilayers. Such stacks may be used in memory applications and three dimensional “not and” gates (3D NAND). These stacks tend to require relatively high aspect ratio (HAR) etching of the dielectrics. For high aspect ratio etches, examples of desired etch characteristics are high etch selectivity to the mask (such as an amorphous carbon mask), low sidewall etching with straight profiles, and high etch rate at the etch front. Some high aspect ratio etches result in tapered features that are much wider at the top than the bottom. Such features may increase device failure or limit device density, device performance, and device depth.

In some etch processes of an OPOP stack with an amorphous carbon mask, during the etch, a metal containing passivant is used during the etch process. The metal containing passivant may be provided during the etch process so that passivation and etching occur simultaneously or there may be alternating steps of passivation and etching. It has been found that when a tungsten (W) passivation is used, the tungsten selectively deposits on the polysilicon with respect to the silicon oxide so that there is less passivation on the silicon oxide than on the polysilicon. The reduced passivation of silicon oxide results in increased defects, such as increased CD and notching. The weakest or thinnest deposition dictates the ability of the passivation layer to protect the underlying material. For example, once the thinner deposition on the oxide degrades during additional etching, the oxide can begin to be etched even if the Si still has tungsten passivation. The etching of the oxide causes CD to increase as well as additional defect formation such as notching, keyholes, etc. Non-uniform passivation may also cause profile twisting, kink, and ion sided bowing.

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack is provided. A metal or metalloid containing mask is formed over the stack. The stack is etched through the metal or metalloid containing mask, wherein the etching sputters metal or metalloid in the metal or metalloid containing mask and the sputtered metal or metalloid physically redeposits on sidewalls of features etched in the stack as a sputtered metal or metalloid containing passivation layer.

In another manifestation, a method for forming a substrate support for use in a plasma processing chamber is provided. A base plate is provided with a substrate support region and a shoulder surrounding the substrate support region. A protective coating thermal is sprayed on a surface of the base plate, wherein the protective coating covers at least part of the shoulder. A layer of a silane coupling agent is deposited on the protective coating.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of processes used in some embodiments.

FIGS. 2A-D are schematic cross-sectional views of a stack processed according to some embodiments.

FIG. 3 is a schematic view of an etch chamber that may be used in some embodiments.

FIG. 4 is a schematic view of a computer system that may be used in practicing some embodiments.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Dry development of high aspect ratio contacts requires strict control of the tapering angle of the sidewall. Various methods try to limit lateral critical dimension (CD) differences between the top and bottom parts of the etched structures. With the recent development of 3D NAND memory having thicker structures with an increased number of ONON or OPOP bilayers, the demand for tight control of top and bottom geometries is especially significant. In case the profile (difference between the top and bottom CDs) increases, subsequent steps of device manufacturing will be at risk that will impact device performance. In the current technology, reactive ion etching of high aspect ratio structures relies on sidewall deposition to protect against CD lateral erosion. A delicate balance between etching and sidewall deposition is especially difficult to maintain for high aspect ratio features. As a result, high aspect ratio dry development is limited to thinner structures and requires significant complex development to enable a thick stack to be etched.

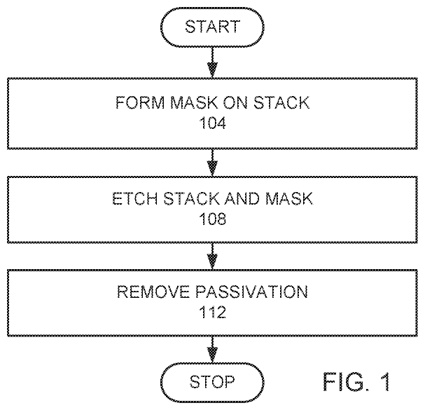

Embodiments described herein provide deeper high aspect ratio features etched in a stack, where widths of the features near the top of the features are about equal to widths of the features near the bottoms of the features. To facilitate understanding, FIG. 1 is a high level flow chart that may be used in some embodiments. A metal or metalloid containing mask is deposited on a stack (step 104). In some embodiments, a plasma enhanced physical vapor deposition (PECVD) is used to deposit a metal containing dielectric film that may be used as a mask. A method of using PECVD to deposit a tungsten carbide film is described in U.S. Pat. No. 9,875,890, entitled “Deposition of Metal Dielectric Film for Hardmask,” issued on Jan. 23, 2018, which is incorporated by reference for all purposes and may be used in some embodiments. In some embodiments, the deposited tungsten carbide film is patterned to form a mask.

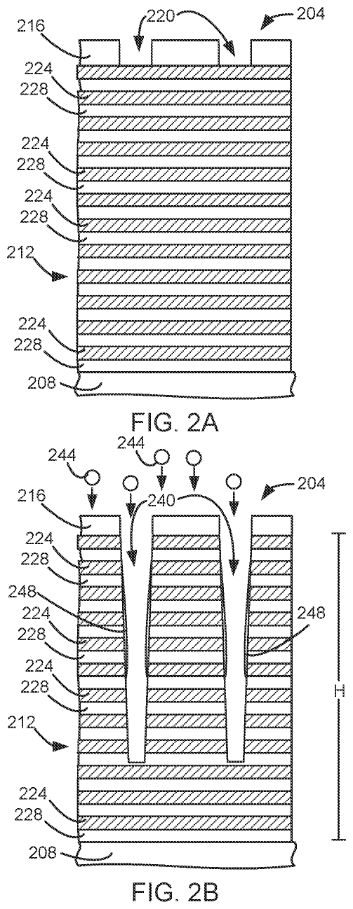

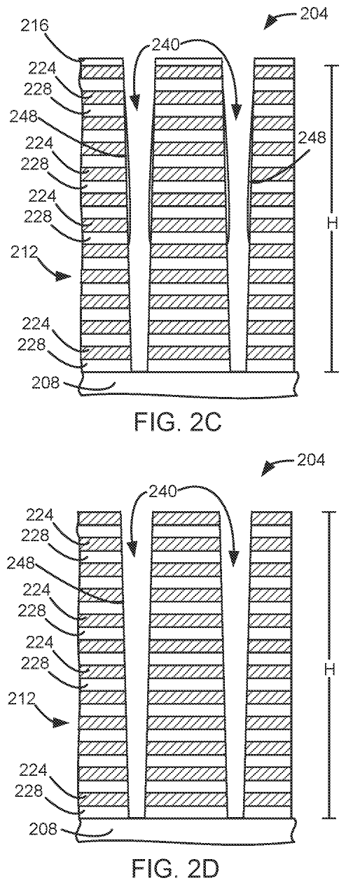

FIG. 2A is a schematic cross-sectional view of a stack 204 that may be etched in some embodiments. In some embodiments, the stack 204 comprises a substrate 208 under a plurality of bilayers 212 disposed below a patterned mask 216. In some embodiments, one or more layers may be disposed between the substrate 208 and the plurality of bilayers 212 and/or the plurality of bilayers 212 and the patterned mask 216. The patterned mask 216 is a metal or metalloid containing mask. In some embodiments, the patterned mask 216 is an amorphous carbon mask doped with tungsten. In some embodiments, the patterned mask pattern provides mask features 220 for high aspect ratio contacts. In some embodiments, the mask features 220 are formed before the stack 204 is placed in the etch chamber. In other embodiments, the mask features 220 are formed while the stack 204 is in the etch chamber. In some embodiments, each bilayer 212 includes a layer of silicon oxide 224 and a layer of silicon nitride 228.

The stack and mask are etched (step 108). In some embodiments, an etching gas is provided. In some embodiments, the etching gas is a metal and metalloid free gas. In some embodiments, RF power is provided to transform the etching gas into a plasma with etching ions. A voltage is applied to accelerate etching ions from the plasma to the stack. In some embodiments, metal and metalloid free etching ions are provided from an ion source and accelerated to the stack. The etching ions etch the stack and sputter metal and metalloid from the mask. The etching of the stack may comprise at least one of a chemical etching and physical sputtering of the stack.

FIG. 2B is a schematic cross-sectional view of a stack 204 during the etching to form partially etched features 240 and depositing tungsten containing passivation sputtered from the mask 216. Etching ions 244 are accelerated towards the stack 204. The etching ions 244 etch the stack 204 forming the partially etched features 240 and sputter some of the mask 216. In some embodiments, the etching ions 244 provide two separate processes for depositing metal or metalloid passivation on sidewalls of the features 240. In one process, the etching ions 244 sputter metal or metalloid atoms from the mask 216 into the plasma creating metal or metalloid species. The metal or metalloid species in the plasma are chemically deposited on sidewalls of the features 240. In a second process, metal or metalloid is sputtered from the mask 216 and is redeposited on sidewalls of the partially etched features 240. In some embodiments, a sputtered metal or metalloid containing passivation layer 248 is formed by both the chemical deposition of metal or metalloid passivation and the physical sputtering of metal or metalloid. This physical sputtering mechanism overcomes the reduced metal or metalloid containing deposition that can be obtained from a chemical or ion assisted deposition process specifically on silicon oxide, allowing for a more uniform passivation layer.

In some embodiments, the etching of the stack is continued until the etching of the stack is completed. FIG. 2C is a schematic cross-sectional view of a stack 204 after the etching the stack 204 is completed. In some embodiments, the features 240 are etched the entire depth of the stack 204. A sputtered metal or metalloid containing passivation layer 248 protects the sidewalls of the features 240 and additionally can provide an increase in vertical etch rate thus reducing overall process times.

In some embodiments, the metal or metalloid containing passivation layer 248 is removed (step 112). In some embodiments, a wet process is used to remove the sputtered metal or metalloid containing passivation layer 248. In some embodiments, a dry process is used. FIG. 2D is a schematic cross-sectional view of a stack 204 after the sputtered metal or metalloid containing passivation layer 248, shown in FIG. 2C, has been removed. In some embodiments, the mask 216, shown in FIG. 2C, is removed in the same process used to remove the sputtered metal or metalloid containing passivation layer. In some embodiments, the mask is removed using a different process used to remove the sputtered metal or metalloid containing passivation layer.

One major issue during high aspect ratio (HAR) etch is CD scaling, specifically as desired features become vertically scaled there is a simultaneous push to keep lateral feature size constant. In practice, this can be very difficult to achieve and many of the current technologies have tradeoffs. In some embodiments, a tungsten doped carbon hard mask is utilized not only to protect the stack from undesired etch but also to provide robust tungsten species that deposit on the sidewall of the etch feature and protect from additional lateral etch. This robust tungsten containing passivation on the sidewall of the feature allows for CD control and prevents other defect formation, such as notching. Additionally, some embodiments allow for both chemical deposition from tungsten species, but also the direct physical sputtering of tungsten doped carbon, thus providing more uniform passivation at the top of the feature.

Some embodiments have been found to provide highly uniform passivation that is better at preventing additional lateral etch rate and defect formation, such as notching, by depositing more tungsten containing species on SiO₂ that is not limited to previous deposition quality/thickness of tungsten on SiO₂ provided in the previously used processes. Some embodiments provide improvements in several ways because the tungsten needed to generate the protective liner material comes from the mask material itself. The improvement provided in some embodiments is from the liner deposition mechanism. The sputtering of the tungsten from the mask causes molecular tungsten species to be added as a reactant gas but also causes physical sputtering of tungsten doped carbon mask material to redeposit on sidewalls. Therefore, both a chemically assisted deposition process (from tungsten by-product formation) and a physical sputtering process (from carbon doped with tungsten) are occurring, the combination of which allows for very uniform deposition across different materials in the etch feature. Overall, this significantly helps protect the top area in the feature from lateral etch and defect formation (notching) both on the bare Si and SiO₂ materials.

Some embodiments may be used on an Oxide/Nitride (ONON) multilayer stack to form features, such as contact holes or trenches, in making a 3D NAND memory device. Some embodiments may be used for dynamic random access memory (DRAM) Capacitor etching. Some embodiments may be used to etch silicon oxide and polysilicon bilayers (OPOP). Some embodiments provide an etch depth of greater than 1 micron. In some embodiments, the etch depth is greater than 10 microns.

An advantage of some embodiments is the ability of a device manufacturer to be able to have a more precise control of the profile of a high aspect feature. Various embodiments enable increasing the bottom CD for very high aspect features. Various embodiments enable the next generations of devices that rely on deeper structures with higher aspect ratios. Various embodiments reduce the cost of device manufacturing by reducing the number of steps for the development of high aspect ratio contacts. Various embodiments reduce the variation of the width of the features along the depth of the features so that the difference between widths at any two points along the depth of the features 240.

In some embodiments, the stack may be a single silicon containing layer, such as a single layer of silicon oxide, silicon nitride, or silicon. In some embodiments, the stack may comprise a single layer or multiple layers of other silicon containing materials.

In some embodiments, the mask 216 is a single layer of a mask material, wherein the metal or metalloid makes up 1% to 50% by weight of the mask material.

In some embodiments, for etching a stack with a silicon layer, the mask may further comprise oxygen. In some embodiments, for etching a silicon oxide stack, the mask may further comprise silicon. Some embodiments may have other materials in addition to the metal or metalloid dopant. In some embodiments, the metal in the metal or metalloid containing mask is at least one of tungsten, molybdenum, ruthenium, tantalum, titanium, platinum, and aluminum. In other embodiments, the metalloid is boron. In some embodiments, the etching gas is metal and metalloid free, since metal and metalloid species are provided by sputtering of the metal or metalloid containing mask.

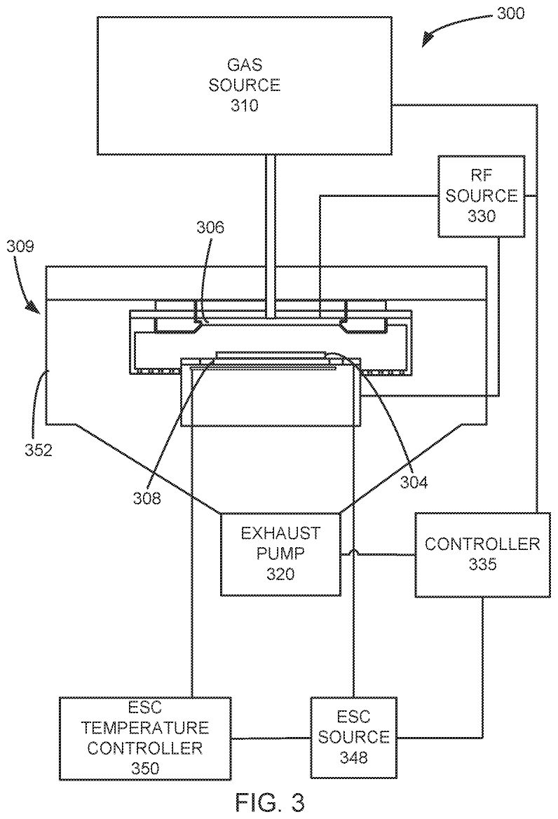

FIG. 3 is a schematic view of an etch reactor system 300 that may be used in some embodiments. In some embodiments, an etch reactor system 300 comprises a gas distribution plate 306 providing a gas inlet and an electrostatic chuck (ESC) 308, within an etch chamber 309, enclosed by a chamber wall 352. Within the etch chamber 309, a stack 304 is positioned over the ESC 308. The ESC 308 may provide a bias from the ESC source 348. An etch gas source 310 is connected to the etch chamber 309 through the gas distribution plate 306. An ESC temperature controller 350 is connected to the ESC 308. A radio frequency (RF) source 330 provides RF power to a lower electrode and/or an upper electrode, which in this embodiment are the ESC 308 and the gas distribution plate 306, respectively. In some embodiments, 400 kilohertz (kHz), 60 megahertz (MHz), and optionally, 2 MHz, 27 MHz power sources make up the RF source 330 and the ESC source 348. In some embodiments, the upper electrode is grounded. In some embodiments, one generator is provided for each frequency. In some embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 335 is controllably connected to the RF source 330, the ESC source 348, an exhaust pump 320, and the etch gas source 310. An example of such an etch chamber is the Flex™ etch system manufactured by Lam Research Corporation of Fremont, CA. The process chamber can be a CCP (capacitively coupled plasma) reactor or an ICP (inductively coupled plasma) reactor.

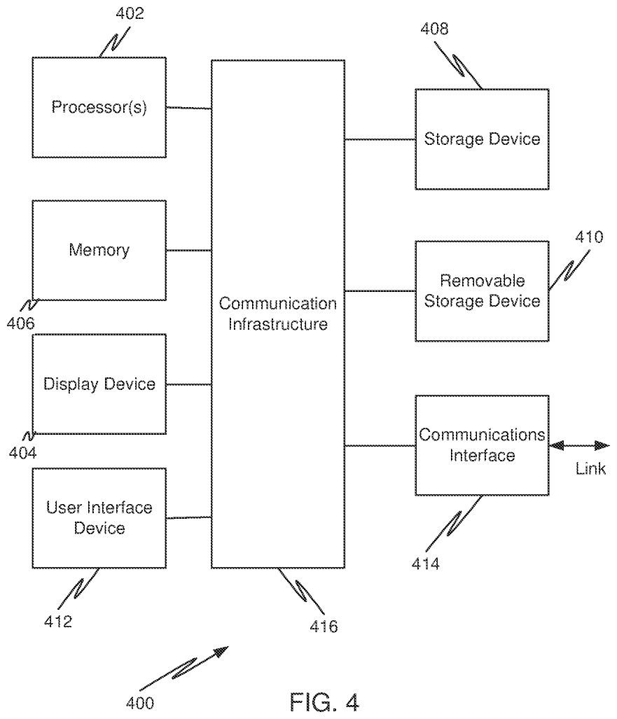

FIG. 4 is a high level block diagram showing a computer system 400, which is suitable for implementing the controller 335 used in embodiments. The computer system 400 may have many physical forms ranging from an integrated circuit, a printed circuit board, and a small handheld device up to a huge supercomputer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communications interface 414 (e.g., wireless network interface). The communications interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communications link that carries signals and may be implemented using wire or cable, fiber optics, a phone line, a cellular phone link, a radio frequency link, and/or other communications channels. With such a communications interface 414, it is contemplated that the one or more processors 402 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that is executed by a computer using an interpreter. Computer readable media may also be computer code transmitted by a computer data signal embodied in a carrier wave and representing a sequence of instructions that are executable by a processor.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for etching features in a stack, comprising:
a) forming a metal or metalloid containing mask over the stack; and
b) etching the stack through the metal or metalloid containing mask, wherein the etching sputters metal or metalloid in the metal or metalloid containing mask and the sputtered metal or metalloid physically redeposits on sidewalls of features etched in the stack as a sputtered metal or metalloid containing passivation layer.

2. The method, as recited in claim 1, wherein the etching the stack comprises:
providing metal and metalloid free etching ions; and
accelerating the etching ions to the stack, wherein the etching ions etch features in the stack and sputter metal or metalloid from the metal or metalloid containing mask.

3. The method, as recited in claim 2, wherein the metal or metalloid containing passivation layer provides metal or metalloid species.

4. The method, as recited in claim 3, wherein the metal or metalloid species chemically deposits on sidewalls of the features in addition to the sputtered metal or metalloid physically redeposited on sidewalls of features.

5. The method as recited in claim 1, wherein the metal or metalloid is at least one of tungsten, molybdenum, ruthenium, tantalum, titanium, platinum, aluminum, and boron.

6. The method, as recited in claim 1, wherein the stack is a silicon containing stack.

7. The method, as recited in claim 1, wherein the stack is a silicon oxide containing stack.

8. The method, as recited in claim 1, wherein the stack is a plurality of alternating layers, wherein at least one layer of the alternating layers is a silicon oxide containing layer.

9. The method, as recited in claim 1, further comprising removing the sputtered metal or metalloid containing passivation layer.
